(19) United States
(12) Patent Application Publication
(10) Pub. No.: US 2014/0042390 A1
(43) Pub. Date: Feb. 13, 2014

(54) INTERPENETRATING NETWORKS OF CARBON NANOSTRUCTURES AND NANO-SCALE ELECTROACTIVE MATERIALS

(71) Applicant: THE REGENTS OF UNIVERSITY OF CALIFORNIA, Oakland, CA (US)

(72) Inventors: George Gruner, Los Angeles, CA (US); Xiangfeng Duan, Los Angeles, CA (US); Bruce S. Dunn, Los Angeles, CA (US); Veronica Augustyn, Los Angeles, CA (US)

(73) Assignee: THE REGENTS OF UNIVERSITY OF CALIFORNIA, Oakland, CA (US)

(21) Appl. No.: 13/963,973

(22) Filed: Aug. 9, 2013

Related U.S. Application Data
(63) Continuation of application No. PCT/US2012/025523, filed on Feb. 16, 2012.
(60) Provisional application No. 61/443,434, filed on Feb. 16, 2011.
(60) Provisional application No. 61/682,140, filed on Aug. 10, 2012.

(51) Int. Cl. H01M 4/36; H01M 4/583; H01L 29/16; H01G 9/042; H01G 9/048; H01L 29/15; H01M 4/48; H01M 4/64

(52) U.S. Cl. CPC H01M 4/364; H01M 4/48; H01M 4/583; H01M 4/64; H01G 9/042; H01G 9/048; H01L 29/15; H01L 29/1606
USPC 257/14; 428/323

(57) ABSTRACT

An interpenetrating network assembly with a network of connected flakes of nano-scale crystalline carbon and nano-scale particles of an electroactive material interconnected with the carbon flakes is provided. The network assemblies are particularly suited for energy storage applications that use metal oxide electroactive materials and a single charge collector or a source and drain. Interpenetrating networks of graphene flakes and metal oxide nanosheets can form independent pathways between source and drain. Nano-scale conductive materials such as metal nanowires, carbon nanotubes, activated carbon or carbon black can be included as part of the conductive network to improve charge transfer.

### CROSS-REFERENCE TO RELATED APPLICATIONS

This application is a 35 U.S.C. §111(a) continuation of PCT international application number PCT/US2012/025523 filed on Feb. 16, 2012, incorporated herein by reference in its entirety, which is a nonprovisional of U.S. provisional patent application Ser. No. 61/443,434 filed on Feb. 16, 2011, incorporated herein by reference in its entirety. This application is a nonprovisional of U.S. provisional patent application Ser. No. 61/682,140 filed on Aug. 10, 2012, incorporated herein by reference in its entirety.

The above-referenced PCT international application was published as PCT International Publication No. WO 2012/112818 on Aug. 23, 2012 and republished on Oct. 18, 2012, and is incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### BACKGROUND OF THE INVENTION

1. Field of the Invention

This invention pertains generally to synthesis schemes and methods for producing networks of carbon containing nanostructures and inorganic nano-scale materials, and more particularly to the synthesis and use of networks of interconnected and interpenetrating networks of crystalline carbon, electroactive nano-scale materials and nano-scale conductive materials and devices made with these networks.

2. Description of Related Art

Electrode materials play a central role in a variety of devices, including energy storage, electronic and opto-electronic devices. Batteries and supercapacitors require electrodes with high electrochemical activity and large electrical conductivity. Opto-electronic devices require light sensitive materials in combination with electrically conductive materials. Solar cells and light emitting diodes (LEDs) also require optically transparent and highly conducting electrodes.

There is an increased demand for energy storage devices that can store and deliver substantial energy and power. Today, batteries are the preferred choice for the majority of applications that require energy storage. For example, lithium ion battery technology has an energy storage capacity of 100 Wh/kg. However, Li⁺ ion insertion is slow, limiting the power that can be delivered, and the charging time for these batteries is comparatively long.

Electrochemical or supercapacitors represent alternative charge storage devices to batteries that possess high power density, reversibility and long cycle life. Generally, supercapacitors can be charged and discharged rapidly and thus have excellent power recovery and delivery, but they lack the energy storage performance of advanced batteries.

There are two predominant charge-storage mechanisms at work in supercapacitors: double-layer capacitance and charge-transfer-reaction pseudocapacitance. The specific capacitance of a supercapacitor may be attributed to one or both of these mechanisms. Double-layer capacitance normally results from the separation of charge at the interface between high surface area electrodes and liquid electrolytes. The capacitance, and thus the energy storage capacity for double layer supercapacitors where the energy is stored at the interface between the electrode and the electrolyte formed by two carbonaceous electrodes, is proportional to the surface area of the electrodes. Typical energy and power values for double layer supercapacitors are 5 Wh/kg and up to 10 kW/kg respectively.

Pseudocapacitance arises from reversible faradaic electrochemical reactions taking place at or near the surface of an electrode over a suitable range of electrical potentials. Transition metal oxides have been shown to be useful electrode materials that utilize pseudocapacitance as the charge storage mechanism. There has been a concentrated effort in recent years to increase the energy storage capacity of supercapacitors and advanced batteries by using materials which have significant electrochemical activity, characteristically due to faradaic reactions at the surface or in the bulk.

In addition to the electrochemical process based charge storage that occurs in batteries and supercapacitors, there is also a need for materials that that display significant electrochemical activity and respond to an external stimulus such as light. Such activity can be used for energy generation devices such as solar cells, and devices such as light emitting diodes. In all these cases the material is in contact with a charge collector in addition to a medium, such as an electrolyte that is inductive of the electrochemical activity.

Accordingly, there is a need for charge-storage materials and methods for reliably producing electrodes and conductive films that are useful in many different applications. There is also a need for a nano-scale electrically conducting material that, in combination of other nano-scale materials, can act as electrode for energy storage and optoelectronics devices and can be processed by a room temperature, solution based fabrication process. The present invention satisfies these needs as well as others and is generally an improvement over the art.

### BRIEF SUMMARY OF THE INVENTION

The present invention is directed to charge-storage materials that can be used in a variety of applications including composites, electronic devices, sensors, photodetectors, batteries, ultracapacitors, solar cells and other devices that use electrodes. The invention is also directed to graphene-functionalized pyrene conjugates and graphene transistor arrays.

By way of example, and not of limitation, the invention provides functional electronic materials with structures that are preferably composed of an interconnected network of carbon nanostructures such as graphene flakes and nano-scale materials. A nano-scale material is a finite sized material with at least one dimension that is less than 100 nm. Examples of nano-scale materials include nanoparticles, nanowires, nanobelts, nanotubes and nanosheets. The nano-scale materials can also have different functionalities. For example, some materials can exhibit large electrochemical activity when in contact with an electrolyte. Other materials may include light sensitive materials, or oxides that are electrically conducting and optically transparent. Nano-scale materials may also be conductive such as carbon nanotubes, carbon nanosheets, metal nanowires, activated carbon or carbon black nanoparticles.

An electrically conducting nanostructured network that provides the combined functions of a charge collector and a charge conductor in an energy storage device is used to illustrate the invention. In one embodiment, an interconnected network, or film formed from finite sized sheets, called “flakes” of charge storage and electrically conducting materials between a source and drain is described. Other nanometer sized particles of conductors or metal oxides can also be used with the conductive network or with the oxide network.

In another embodiment, a composite electrode architecture is used that includes nano-sheets of an oxide material, such as titanium oxide, together with a nanostructured carbon such as graphene sheets or carbon nanotubes. The carbon-oxide scaffold provides (1) high surface area, (2) high electrical conductivity, and (3) the network of the nano-sheets of the oxide material provides the high surface area for faradaic surface reactions.

For the purposes of this illustration, the oxide flakes are oxide materials, such as TiO₂ composed of single sheets or a few sheets, where at least one length or width dimension is less than 100 nm. The oxide flakes are typically less than 10 sheets of material.

Graphene is defined as sheets of carbon atoms bonded together in a two-dimensional honeycomb lattice structure one atom thick that possess remarkable in-plane mechanical, thermal, optical and electronic properties. Graphene is electrically and thermally conductive and has a comparatively high fracture strength, Young's modulus and functional surface area. These properties make graphene a good candidate for use in electrode applications. Graphene flakes are defined as single or multiple layers of graphene sheets having either length or width less than 100 nm.

The graphene flakes and nano-scale materials form an interconnected network, in contrast to two films (a graphene film and a film composed of nanoparticles) on top of each other. In a second embodiment, the graphene flakes act as a conducting channel of a transistor that can be formed into an array of transistors.

According to one aspect of the invention, an interconnected network of carbon nanostructures such as grapheme flakes and nano-scale charge retaining materials in the form of nanoparticles, nanowires or nanosheets of an oxide, a sulphide or a selenide is provided. The graphene flakes can be in direct contact with another flake or tethered by conductive nanotubes or nanowires in one embodiment.

Another aspect of the invention is to provide an interconnected network of carbon nanostructures such as grapheme flakes and nano-scale materials that form continuous pathways between a source and a drain.

A further aspect of the invention is to provide an interpenetrating network of graphene flakes, nano-scale materials and nano-scale conductive materials such as activated carbon, carbon nanotubes, metal nanowires and carbon black.

Another aspect of the invention is to provide an interpenetrating network of graphene flakes, nano-scale electrochemical materials, nano-scale conductive materials and a second nano-scale material where two, three or all four networks form a continuous path between a source and drain. For example, the second nano-scale electroactive material can be the same material as the first in a different form or it can be a different material from the first in any form.

Another aspect of the invention is to provide nano-scale electrochemical materials such as oxide, sulphide or selenide sheets and conductive nano-particles such as Ag nanowires, ZnO nanowires, ITO nanowires, semiconducting nanowires, polyaniline nanofibers, carbon nanotubes, activated carbon and carbon black.

According to a further aspect of the invention, energy storage devices such as supercapacitors where both the anode and cathode are composites and the each electrode includes a different type of oxide flake. For example, preferred oxide nano-sheet materials for the typical anode and cathode materials in energy storage devices include titanium oxide TiO₂ or Li₂MSiO₄ (where M is a transition metal) in combination with a nano-structured carbon such as a carbon nanotube. Nanosheets including sulphides and selenides are also suitable electrochemical materials.

According to another aspect of the invention, a thin film transistor with a graphene and oxide composite is provided.

Yet another aspect of the invention is to provide a transistor using porphyrin or pyrene-tethered quantum dots that can be conjugated onto graphene transistors through π-π interaction for light-sensing devices.

Another aspect of the invention is to provide a graphene transistor array where each transistor element is functionalized with a different nano-scale functional material.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic top view of a network of interconnected carbon nanostructures such as sheets of graphene bridging a source and drain.

FIG. 2 is a schematic top view of an interconnected network of grapheme flakes and nano-scale materials in the form of nanoparticles, nanowires or nanosheets according to the invention.

FIG. 3 is a schematic top view of interconnected networks of grapheme flakes and nano-scale materials where both networks form a continuous path between the source and drain.

FIG. 4 is a schematic top view of an interpenetrating network of graphene flakes, nano-scale materials and nano-scale conductive materials.

FIG. 5 is a schematic top view of an interpenetrating network of graphene flakes, nano-scale materials and nano-scale conductive carbon materials where two or all three networks form a continuous path bridging between the source and drain.

FIG. 6 is a diagram depicting molecular conjugation through a π-π interaction between a graphene sheet and functionalized pyrene molecules.

FIG. 7A depicts a porphyrin and FIG. 7B depicts pyrene-tethered quantum dots that can be conjugated onto graphene transistors through π-π interactions for use in light-sensing devices.

FIG. 8 is a schematic diagram of a graphene transistor array where each transistor element is functionalized with different nano-scale functional material.

FIG. 9 is a plot of Cyclic Voltammetry (CV) results from 1 to 100 mV/s of the lithium cell.

FIG. 10 is a plot of the log(peak current) versus log(sweep rate) to determine the b-value.

FIG. 11 is a plot of capacity versus time for lithium insertion (cathodic) and deinsertion (anodic).

### DETAILED DESCRIPTION OF THE INVENTION

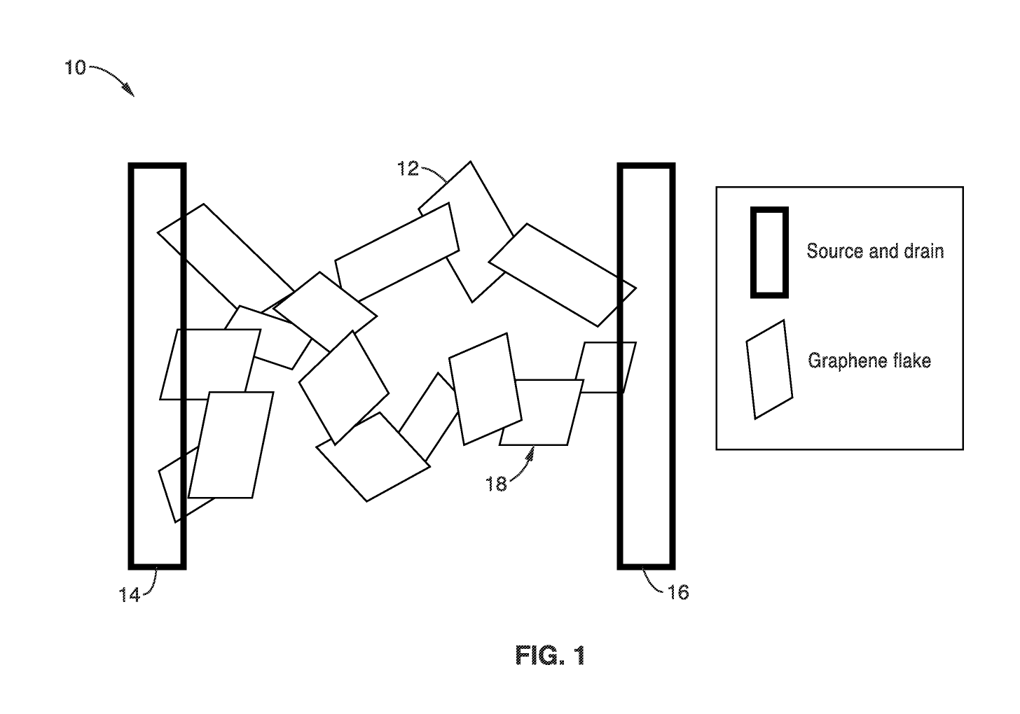

Referring more specifically to the drawings, for illustrative purposes several embodiments of the interpenetrating networked films of the present invention are depicted generally in FIG. 1 through FIG. 5 and the associated methods for producing the films. It will be appreciated that the methods may vary as to the specific steps and sequence and the film architecture may vary as to structural details, without departing from the basic concepts as disclosed herein. The method steps are merely exemplary of the order that these steps may occur. The steps may occur in any order that is desired, such that it still performs the goals of the claimed invention.

As seen in the schematic embodiments illustrated in FIG. 1 through FIG. 5, the general structure is an interconnected network of carbon nanostructures such as graphene flakes, nano-scale charge retaining materials in the form of nanoparticles, nanowires or nanosheets, and optionally nano-scale conductive materials are disposed on current collectors.

The term “nanostructured network” or “interpenetrating network” is intended to refer to randomly and/or semi-randomly ordered nanostructures that are in electrical connection with each other. An “interpenetrating network” may also include two or more independent networks that are functionally connected with each other as illustrated in FIG. 3 and FIG. 5.

A nanostructured network is organized from nano-scale components that can be in a variety of forms and composed from a variety of materials. The term nano-scale component is intended to have a broad meaning to include any nanoparticle structure or form that has at least one dimension that is less than approximately 100 nm and greater than approximately 1 nm and may include nanotubes, fullerenes, nanowires, nanoribbons, nanosheets, nanoplates, and nanorods, etc.

Preferred nanostructured carbon includes graphene sheets or carbon nanotube (CNT) components. Graphene flakes are single or multiple layers of graphene sheets, preferably having either length or width less than 100 nm. Carbon nanotubes are highly conducting nano-scale wires of carbon that can form thin films with low sheet resistance. The high electrical conductivity of the carbon nanotube network ensures fast delivery of the charge to the current collector.

For example, the nano-scale materials may be in the form of nanowires. Nanowires may include, but are not limited to, metallic nanowires (e.g., Ag, Ni, Pt, Au), semiconducting nanowires (e.g., InP, Si, GaN), oxide nanowires (e.g., NiO, SiO₂, TiO₂, MnO₂, MoO₃, V₂O₅, and RuO₂) as well as organic nanowires and inorganic nanowires such as ZnO nanowires, ITO nanowires, polyaniline nanofibers and Si nanowires.

As used herein, the term “nanowire” includes any structure that has at least one dimension between about 1 nm and 100 nm, and an aspect ratio with respect to that dimension of at least 10 (e.g., a carbon nanotube with a diameter of 10 nm and a length of 1000 nm). Nanowire networks may comprise at least one interconnected network of such nanowires (e.g., wherein nanowire density of a network or of multiple networks is above a percolation threshold). Nanowire networks may also comprise multiple interpenetrating networks (e.g., first and second networks of nanowires, the elements of which are interspersed).

In another embodiment the nano-scale material is a “nanosheet” that is ideally a single sheet of a regular arrangement of the constituent atoms where at least one length or width dimension is less than 100 nm. Nanosheets may also include laminations of multiple sheets of the above dimensions. Nanosheets can be made from carbon or an oxide or some other electroactive or electrochemical material.

Composite electrode architecture utilizing interpenetrating nanostructured networks of the invention typically includes nanosheets of oxides or sulphides or selenides and interpenetrating networks of nano-structured carbon such as a carbon nanotubes or graphene. These electrodes may also be paired symmetrically with a second composite electrode that has a different oxide or paired asymmetrically with a conventional carbon electrode.

Turning now to FIG. 1, an embodiment of a network 10 of conductive nanostructures is schematically shown. The nano-scale components 12 forming a conductive nanostructure 18 of the interpenetrating network assembly 10 illustrated in FIG. 1 are preferably graphene flakes. Graphene flakes are generally graphene nanosheets defined as a single sheet or layer of carbon atoms, in a hexagonal configuration within the sheet. While a nanosheet is ideally a single sheet or layer of a material in a highly regular configuration of the atoms within the sheet, multiple sheets of up to 10 sheets or layers are also considered to be suitable graphene flakes. The networks described herein may also have single, double and triple nanosheets of graphene together with some fraction of multiple sheets exceeding three sheets.

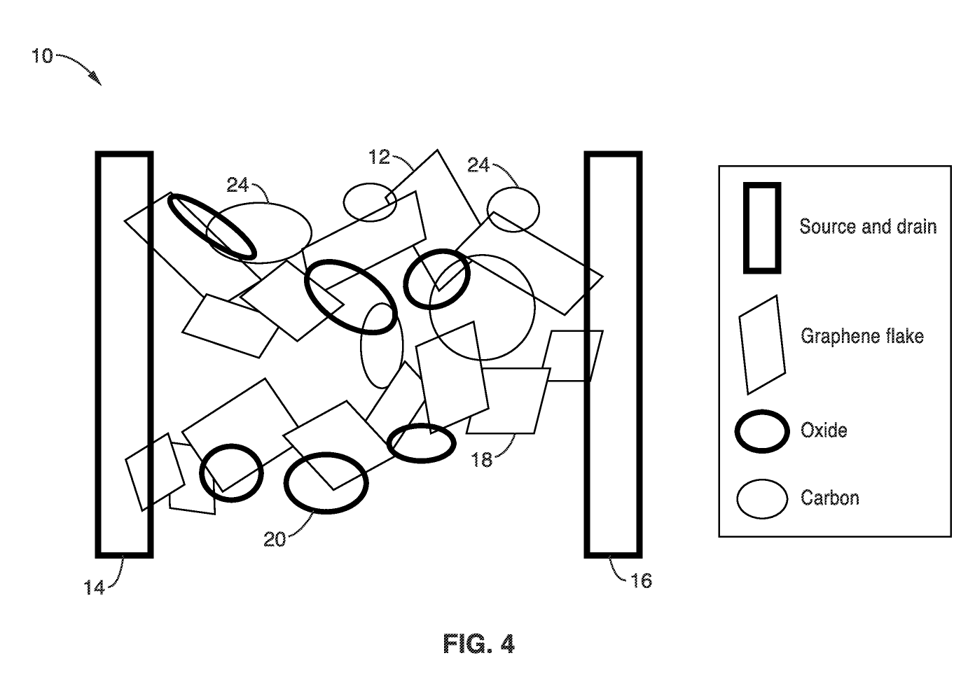

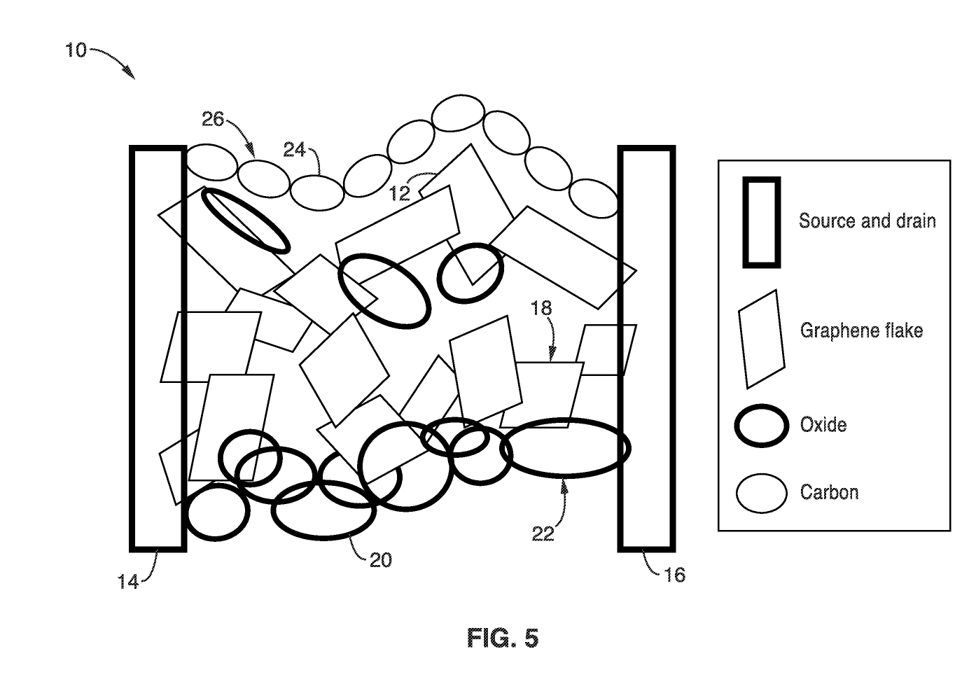

The network assemblies 10 illustrated in FIG. 1 through FIG. 5 refer to a base nanostructure of flakes of graphene 12 that form at least one continuous pathway across the nanostructure 18 of flakes from one electrode to the other. The conductive network assembly 10 may also include other conductive nanoparticles besides graphene as shown in FIG. 4 and FIG. 5. For example, graphene flakes may be connected to other graphene flakes directly and/or by conductive nanoparticles such as metallic nanowires or carbon nanotubes.

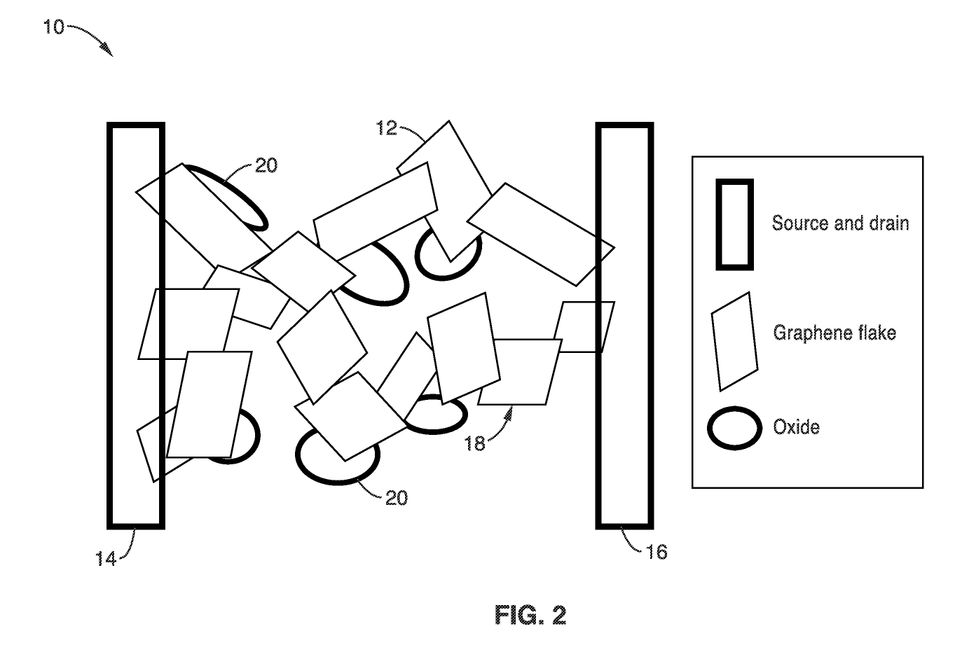

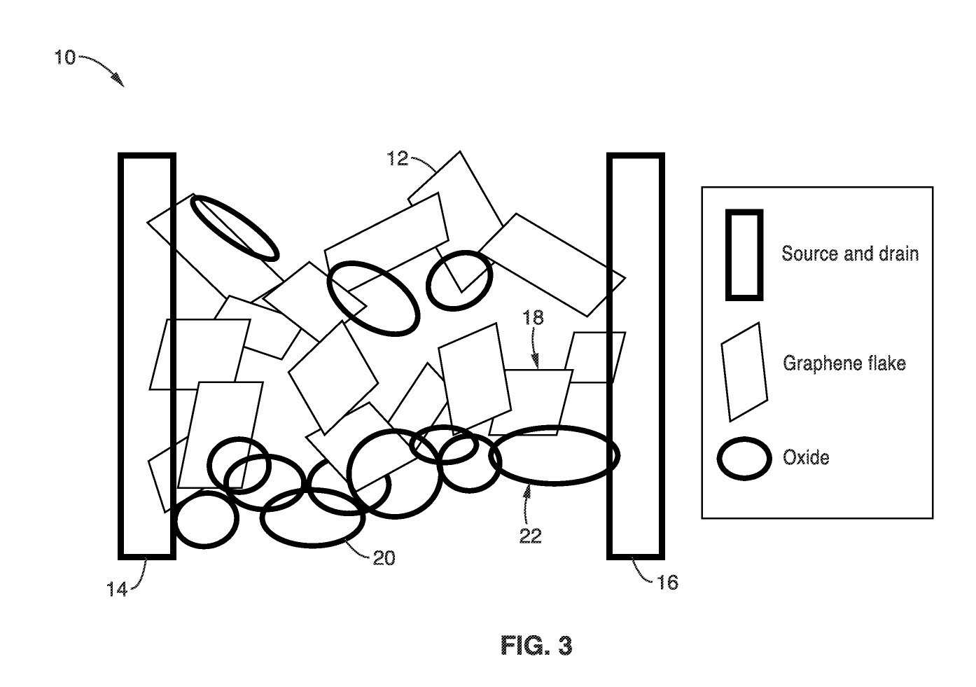

Referring also to FIG. 2 and FIG. 3, the interpenetrating network 10 is an assembly of at least two different types of nano-scale materials, with one of the nanostructures 18 composed of flakes 12 of a conductive crystalline carbon material such as graphene. The conductive graphene nanostructure 18 forms a network of continuous pathways between the two electrodes 14, 16 and the other nano-scale materials may or may not form a continuous pathway between the two electrodes.

As seen in FIG. 2, the conductive nanostructure 18 of electrically interconnected graphene flakes 12 bridges the source 14 and drain 16 while the oxide nano-scale particles 20 are associated with the networked nanostructure 18 but do not bridge the source and drain. The “source” and “drain” are given a broad definition that may include any electrically conducting material such as a metal like aluminum or copper, a conducting paste or a conducting liquid such as an electrolyte.

In this embodiment, the oxide nanoparticles 20 are in functional proximity to other oxide nanoparticles 20 as well as the graphene flakes 12 that form the conductive nanostructure 18 to allow charge storage and charge transfer. When used for energy storage, the oxide material provides the capacitance and the carbon materials provide the electrical conductance. Although oxide nanoparticles 20 are used as an illustration, it will be understood that other nanoparticles of electroactive or electrochemical materials may also be used.

In the embodiment shown in FIG. 3, both the conductive nanostructure 18 and a nanostructure 22 of interconnected oxide nanoparticles 20 form continuous pathways between the source 14 and the drain 16. The graphene 12 components of the conductive network 18 and the oxide nanoparticle components 20 of the oxide nanostructure 22 are also in functional proximity to each other.

The functionality of the interconnected conductive 18 and capacitive 22 nanostructures can be accentuated with other nano-scale materials. For example, conductive nanoparticles such as metal nanowires, semiconductor nanowires or carbon nanotubes can be incorporated as part of the conductive nanostructure 18. Likewise, nano-scale oxide materials could also be included in the capacitive oxide nanostructure 22. For example, the capacitive oxide nanostructure 22 could be formed from nanosheets of one type of oxide and the additional nano-scale oxide material could be oxide nanowires of the same oxide or of a different oxide.

FIG. 4 illustrates one embodiment of an interconnected network with a nanostructure of three components, namely, graphene 18 with oxide nanoparticles 20 as well as conductive nanoparticles 24 that are functionally associated with the graphene network 18 and the oxide nanoparticles 20. The network of graphene flakes, nano-scale materials and nano-scale conductive materials can also be configured to have two, three or four nanostructured networks forming continuous pathways between the source 14 and drain 16.

The carbon nano-scale conductive material is a material with at least one dimension that is less than 100 nm. Examples include carbon nanowires, nanobelts, nanotubes and nanosheets. Carbon nanoparticles 24 can be made of activated carbon, carbon nanotubes, and carbon black. Nanoparticles of carbon containing polymers such as polyaniline can also be used.

Carbon nanotubes can be made from rolled-up sheets of graphene and can also have multiple sheets of carbon atoms forming single wall, double wall and multiwalled nanotubes. Graphene and carbon nanotubes differ from other nano-scale carbonaceous materials such as carbon black and activated carbon in the structure.

The network illustrated in FIG. 5 shows a conductive network 18 of graphene sheets 12, a capacitive network 22 of oxides 20, and a network 26 of conductive nanoparticles such as carbon nanoparticles 24. Each interconnected network 18, 22, 26 is connected with the other networks and all bridge the source 14 and drain 16 so that all three networks form a continuous path between the source 14 and drain 16. Similar constructions can be made with all four components.

It can be seen that there are several variations in forming the interpenetrating networks of graphene flakes and other nano-scale materials that may form continuous pathways between the source 14 and drain 16. However, one preferred interpenetrating network configuration has a conductive network of graphene flakes, a capacitive network of oxide nanosheets and conductive carbon nanotubes. It is also preferred that the interpenetrating network film 10 of connected graphene flakes provides at least one electrical conduction path between the two ends of the film and is disposed on an appropriate substrate.

Exemplary methods of depositing the graphene film onto a substrate include, but are not limited to, vacuum filtration, spray-coating, dip-coating, drop-coating and/or casting, roll-coating, transfer-stamping, slot-die coating, curtain coating, gravure printing, flexoprinting and/or inkjet printing. For example, a filtering method can be used to remove the solvent and surfactant to form an electrode.

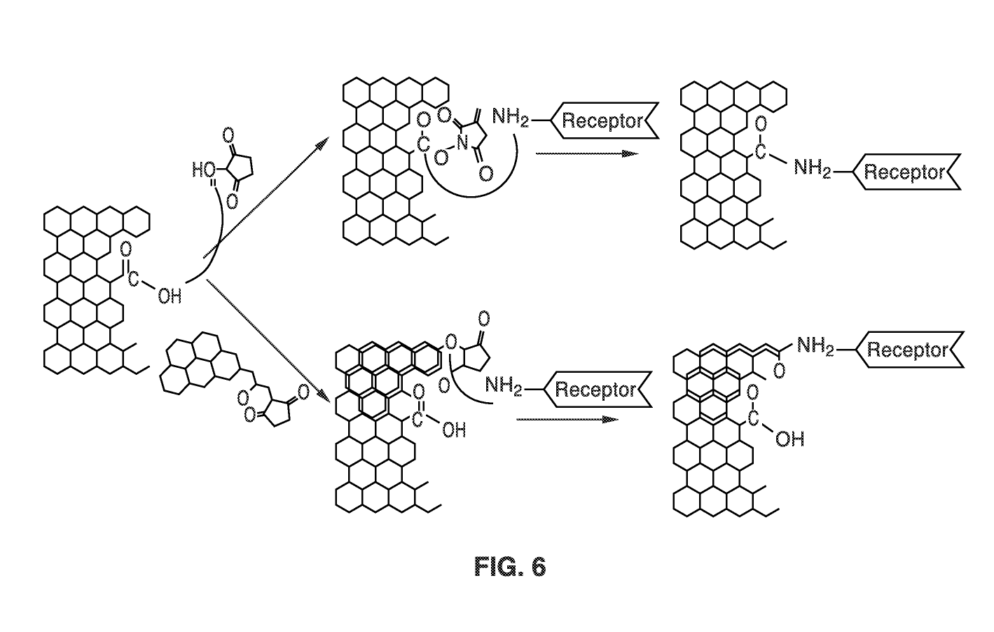

Turning now to FIG. 6 through FIG. 8, films of the interpenetrating networks can also be adapted to other devices besides charge storage devices. For example, the well defined carbon chemistry readily allows hetero-integration of graphene with many different molecular systems resulting in devices that can respond to specific physical, chemical or biological stimulation. In general, there are two potential strategies for functionalizing the graphene and graphene nanostructures. First, the edges of graphene or graphene nanostructures are usually terminated with a large number of carboxylic groups. These groups can be activated using reagents such as 1-ethyl-3-(3-dimethylaminopropyl) carbodiimide (EDC) to react with amine residues on biomolecules such as proteins or other biologically active molecules. Alternatively, the surface of a graphene sheet can interact with pyrene (or other planar π-electron system through a π-π interaction), on which link molecules can be introduced to further link to selected receptor molecules as shown in FIG. 6. The attachment of the receptor molecules that respond to photons, specific chemical or biological species allows the configuration of these graphene based devices into photodetectors, and chemical or biological sensors.

Transistors with a single sheet of graphene as the conducting channel can also be used as a platform. The transistor configuration allows the carrier number and mobility to be separately examined—in contrast to simple resistance measurements where the two are combined into one measured parameter. This permits a detailed examination of fundamental quantities such as charge transfer at the nano-scale interface. In addition, the unique structural, chemical and electronic properties of graphene can produce highly sensitive chemical and biological sensors. In particular, several attributes should be noted: (1) with classical physical approximation, the detected signal, the change of S=Δn·μ·e, where Δn is the carrier concentration change brought by the binding of the target molecules, μ is the mobility and e is elementary charge. Therefore, the exceptionally high mobility (μ) of graphene transistors leads to extraordinarily high voltage (charge) sensitivity. (2) The conducting channel graphene transistors are formed by a single layer of carbon atoms (and also that of nanoribbon or nanomesh is formed by nano-scale channels of single atom thick graphene) with the largest achievable surface to bulk ratio. Thus the binding of any charged molecules can result in a large change in the overall conductance to ensure the best sensitivity possible. (3) The well-defined graphene surface with highly delocalized π electrons, and graphene edge carboxylic groups can enable facile chemical modification and immobilization of receptor molecules for the selective detection of specific analytes that bind only to the receptors. (4) The two-dimensional structure of graphene over large areas allows flexible design of devices with desired lateral size and device current to ensure a sufficient signal-to-noise ratio. (5) The availability of large area graphene sheets readily enables fabrication of highly integrated nanosensor arrays for high throughput, multiplexed sensing.

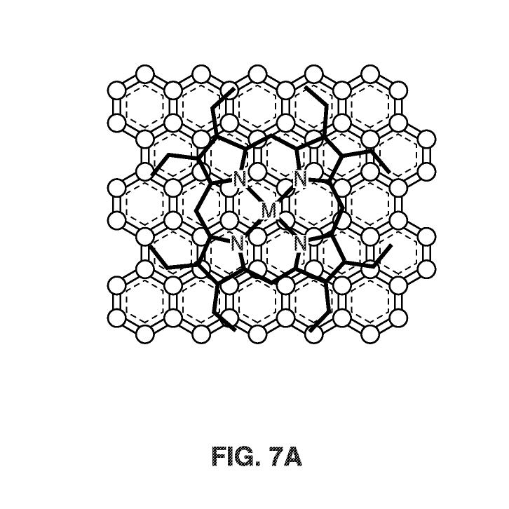

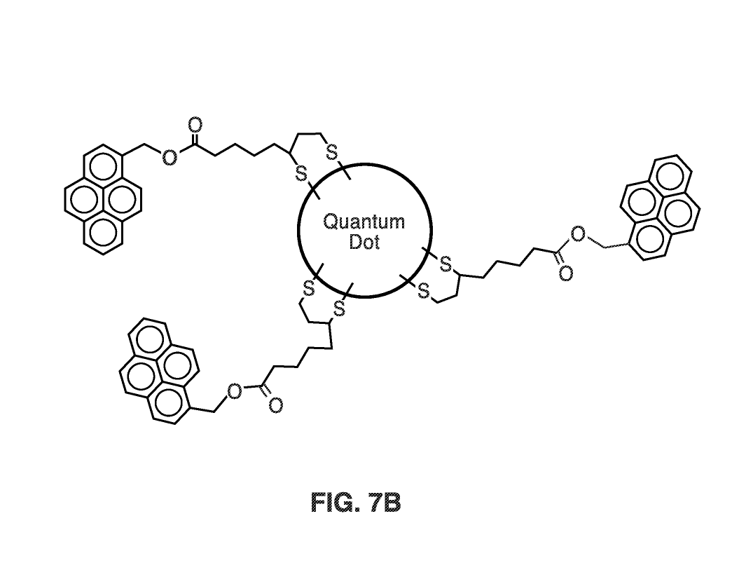

In this embodiment, graphene transistors are interfaced with light sensitive molecules and species. Two species, porphyrins and quantum dots are preferably used as shown in FIG. 7A and FIG. 7B. For both species, environmental stimulus (light) induced changes of the electron configurations occur and these changes translate into changes of the charge transfer between these species and graphene leading to changes in the characteristics of the transistor response. Most porphyrins and their metalloporphyrins, with different spectral responses, may be used for the functionalization of graphene. The use of various metals (such as Cu²⁺, Ni²⁺, Zn²⁺, Fe³⁺) will allow the coordination of the interactions between the porphyrin derivatives and graphene within the hybrids and produce individual graphene-porphyrine assemblies with different spectral responses. The preferred quantum dots that will be suitable for use are various semiconductors including CdSe, CdS, CdSe/ZnS. These are anchored by pyrene functionalization.

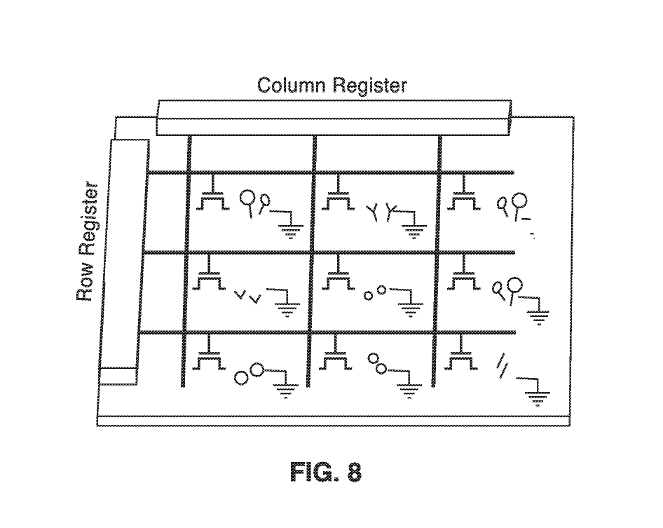

Accordingly, these individual transistors can be arranged into highly integrated graphene-molecular device arrays. The two-dimensional nature of graphene can readily allow the fabrication of large arrays of graphene transistors. Selective functionalization and graphene transistors in such an array with different receptor molecules can enable a highly parallel and multiplexed detection system. In general, an independently addressable device array can be achieved through an active matrix control circuit as illustrated schematically in FIG. 8. The active matrix control circuit can be fabricated using conventional silicon electronics, onto which the graphene transistors can be fabricated and integrated with each pixel.

The individual elements of the matrix are interfaced with light sensitive species that respond to different wavelengths. These species—porphyrines or quantum dots—with different spectral response characteristics, together with the appropriate interrogation electronics will permit a simple color sensor. Large dynamic range will be achieved by using transistors with different characteristics, and also with varying the density/number of light sensitive species that are attached. Similarly, a sensor array with different elements such as markers of certain types of cancers can also be produced. The fabrication of arrays of multiplexed sensors requires selective functionalization of each graphene transistor with distinct receptors. This can be achieved with multiple techniques, including microarray molecular photolithography, dip-pen nanolithography and selective electrochemistry.

Energy storage devices can be designed with electrodes with different configurations. For example, an asymmetrical supercapacitor device can be produced with a composite electrode composed of a TiO₂ nanosheet/carbon nanotube electrode as the anode and a carbonaceous nano-structured material as the cathode.

In another embodiment, a device can be made with architecture that includes two composite electrodes of carbon nanostructures and nanosheets of different oxides. For example, the anodes can be composites composed of nanosheets of TiO₂ or V₂O₅ and the aforementioned carbon nanostructures. The cathodes can be made to include nanoparticles or nanosheets of oxides that can reversibly insert or de-insert lithium without going through a phase change: Li₄Ti₅O₁₂, LiMn₂O₄, LiFePO₄ and LiFeSO₄F. The latter compound is part of a large family of compounds with the general formula: AMSO₄F where A=Li, Na and M=Fe, Co, Ni, Mn. Alternatively oxides that are used in cathodes in Li⁺ ion batteries can also be combined with the nanosheet composites as described before.

The invention may be better understood with reference to the accompanying examples, which are intended for purposes of illustration only and should not be construed as in any sense limiting the scope of the present invention as defined in the claims appended hereto.

### Example 1

In order to demonstrate the functionality of various interpenetrating network films, three different fabrication methods for fabricating interpenetrating networks of graphene flakes and other nano-scale materials were used and the products were evaluated. The first method co-deposited graphene flakes and the nano-scale material using different dispersants for the two species. Each species was dispersed in separate solvents, sonicated to achieve appropriate dispersion, and sprayed using a nozzle that deposits both materials at the same time. Changing the concentration of the materials, and changing the deposition rate will lead to a different concentration of the material species in the composite films.

In one example, oxide nanoparticles were mixed with carbon graphene flakes and polyvinylidene fluoride (PVDF) binder in N-methyl-2-pyrrolidone to create a slurry. A stainless steel sheet was cut into an appropriate length and width and the slurry was painted onto the stainless steel. The typical mass of active material targeted was approximately 2-3 mg. The electrode/current collector was placed into an oven for 24 hours to evaporate the solvent and to create a robust electrode. Following this, the electrodes were placed into a vacuum desiccator for storage for at least an additional 24 hours. Finally, electrodes were prepared with various percentages of graphene.

The second method dispersed the two species in the same liquid with a one-step simultaneous exfoliation and deposition of graphene with metal oxides. In a first example, graphene was dispersed in N-methylpyrrolidone (NMP) by sonication for a period of 1 hour. Then V₂O₅ powder was mixed with de-ionized water at a high concentration and sonicated until the particles disappeared and the solvent turned yellow. A solvent blend with a ratio of 4:1 NMP:H₂O was then created to form a stable dispersion containing both V₂O₅ and graphene. This mixture was drop cast onto a metal plate and the solvents were evaporated by heating in an oven at 120° C. for 1 hour. Alternative solvents include Dimethylformamide (DMF), N,N-Dimethylacetamide (DMA), γ-butyrolactone (GBL), and 1,3-dimethyl-2-imidazolidinone (DMEU). This method can also be used for graphene and LiMoO₃ and other MoO₃ compounds replacing V₂O₅ in the preparation.

As a second example, this method was applied to produce a film of graphene and MnO₂. Stable graphene sheet dispersions were prepared in tetrabutylammonium (TBA) hydroxide mixed with dimethylformamide (DMF). Individual MnO₂ nanosheets were prepared in a TBA hydroxide solution. A stable dispersion containing both types of nanosheets was created by the mixing of solvents in a ratio of 4:1 DMF:TBA. The mixture was drop cast onto a metal plate and the solvents were evaporated by heating in an oven at 120° C. for 1 hour. TBA was removed by repeated washing with deionized water.

The third fabrication method used direct growth of the nano-scale material using the graphene flakes as templates. In this example, titanium tetrachloride (TiCl₄) was added into an ice-cold aqueous hydrochloric acid (HCl) solution that was constantly stirred in a flask. Following this, 1 ml of the stock solution was added into distilled water inside a glass flask. Then polyethylene imine (PEI) was added to the solution. The mixture was covered by aluminum foil and placed into an oven. The presence of TiO₂ was evidenced by the presence of a white powder. Graphene flakes were added to the solution and mixed with a magnetic stirrer. The mixture was then stirred and refluxed. The resulting suspension was centrifuged and the excess liquid was decanted off. The remaining slurry was then filtered and washed with distilled water followed by ethanol. Electrodes were prepared by depositing the slurry onto an appropriate surface.

### Example 2

To illustrate networks of oxide nanosheets, TiO₂ nanosheets were prepared and evaluated. TiO₂ nanosheets were produced by a simple hydrothermal route using tetrabutyl titanate, Ti(OBu)₄, as a source and hydrofluoric acid solution as the solvent. The two were mixed in an autoclave at high temperature, above 180° C. After cooling to room temperature, centrifugation was used to separate the product, followed by washing ethanol and water. The TiO₂ nanosheets that were produced were stable and could be stored in ethanol for electrode processing.

Graphene flakes were then mixed with a polyvinylidene fluoride (PVDF) binder (5 wt. %) in N-methyl-2-pyrrolidone solvent. The mixture was then sonicated for 1 hour. The TiO₂ nanosheets dispersed in ethanol were then added to the mixture and sonicated. The resulting slurry was drop cast onto a stainless steel current collector of an appropriate length and width. The electrode/current collector was placed into an oven to evaporate the solvent and to create a robust electrode.

In an alternative approach, the solution containing the oxide nanosheets was deposited directly from the solution on top of the graphene networks fabricated followed by incubation and rapid shaking of the electrode. In such a multiple network the graphene network acts rather as the current collector whereas the additional coating is the active material. This geometry is fundamentally different from composites where all materials are mixed together and potentially interrupting the current paths within the graphene network.

Multiple networks of oxide nanosheets and graphene flakes, if properly optimized, can lead to electrodes that have high specific capacitance C/gr and high electrical conductivity. In addition, other nano-structured carbons such as activated carbons can also be incorporated into the structure. As an example, nanosheets of TiO₂ (anatase) have an electrochemical capacitance of C=490 F/gr while graphene sheets have a capacitance of 100 F/gr. With a typical composition of 50% of TiO₂ nanosheets and 50% of graphene the resulting electrochemical capacitance is approximately C=290 F/gr.

Electrodes with three components may also possess properties superior to that of two component electrodes as described above. Such three component networks are displayed on FIG. 4 and FIG. 5. Other nano-structured carbons such as activated carbons can also be incorporated into the structure. Electrodes containing oxide nanosheets, graphene and activated carbon were produced as an illustration. In this example, nanosheets of TiO₂ (anatase) have an electrochemical capacitance of C=490 F/gr while grapheme sheets have a capacitance of 100 F/gr and activated carbon 120 F/gr. With a typical composition of 50% of TiO₂ nanosheets and 45% of activated carbon and 5% of graphene the resulting electrochemical capacitance was approximately C=300 F/gr.

### Example 3

The functionality and performance of the electrodes with interpenetrating networks of graphene and materials with large electrochemical capacity for energy storage devices were evaluated. As described above, the electrodes take advantage of both the high conductivity of the graphene and the high specific capacitance of the oxides. The direct electrical contact between the two species ensures that the charges generated by the electrochemical reaction at the surface of the oxide materials will be transferred to the graphene network. Thus high energy density and high power density are ensured.

In one exemplary embodiment of the present invention, an asymmetric supercapacitor may be assembled with an anode comprising interpenetrating networks of carbon graphene and oxide nanoparticles and a cathode comprising interpenetrating networks of graphene and a carbonaceous material (e.g., activated carbon). It should be noted that one or both of the interpenetrating networks of graphene and nanoparticles may have a density above a percolation threshold. Alternatively, the combined interpenetrating networks of nanowires may have a density above a percolation threshold where neither network alone has a density above a percolation threshold.

In one embodiment, asymmetric supercapacitors may be constructed that have one electrode that provides significantly larger capacitance C₁ than the other electrode C₂. Such supercapacitors offer energy density advantages for several reasons: the device capacitance is almost equal to the capacitance of the electrode having the smaller capacitance, since 1/C_{T}=1/C₁+1/C₂. Thus if C₁>>C₂, C_{T}=C₂. In contrast, if C₁=C₂, C_{T}=C/2 for a symmetric supercapacitor. Also, an asymmetric supercapacitor can reliably operate at operating voltages up to about 2V—almost double that of commercially available symmetric capacitors. This higher operating voltage allows an almost a four-fold increase in energy density. Combined, these factors provide an energy density potentially up to eight times that of an electric double layer capacitor.

The performance of asymmetric supercapacitors can be simply evaluated using the capacitance values of carbonaceous and multiple network electrodes. Capacitances exceeding C=200 F/g are readily obtained for a variety of carbon materials, including aerogels, activated carbons and carbon-conducting polymer composites. Capacitances up to 800 F/gr have been reported for ruthenium oxides, and 800 F/gr for MoO₃. Assuming the latter value and a voltage window of 1.6V, performance of asymmetric supercapacitors according to embodiments of the present invention can achieve an energy density of 30 Wh/kg.

### Example 4

Electrochromic (EC) devices often require flexible transparent electrodes disposed on plastic substrates. Many electrochemically driven electrochromic devices involve the use of erosive solid or liquid electrolytes and therefore Indium-Tin-Oxide (ITO) on flexible substrates cannot be used. One approach to this problem has been the use of conducting polymers such as poly(3,4-ethylenedioxythiophene)poly(styrenesulfonate) (PEDOT/PSS) to prepare transparent electrodes. However, the conductivity of conductive polymers as well as their thermal and chemical stability still needs to be improved.

Graphene films that incorporate nanowires can be used as transparent electrodes, and a conducting polymer, polyaniline (PANI), can be used as the electrochromic active material. The color of PANI can be electrochemically tuned by applying different potentials and the use of PANI as the active material for EC devices has been previously demonstrated using ITO on glass as the transparent electrodes. Another advantage of using PANI is that it can be conveniently deposited on the electrodes by a simple electrochemical reaction in an acidic solution. PANI can be electrochemically grown on even ultrathin transparent graphene networks, which can then be immediately used for EC devices.

Light emitting diodes can also be fabricated using graphene composite films as anodes, in combination with other transparent materials such as indium tin oxide ITO. The ITO component provides the high transparency, the graphene flakes providing the high mechanical flexibility needed for many applications.

### Example 5

The combination of graphene flakes and functionalized nanoparticles was demonstrated with the fabrication of CdSe and graphene composites. The surfaces of CdSe nanoparticles were functionalized with a pyrene derivative of di-hydrolipoic acid in H₂O/N,N-dimethylformamide (DMF) solution. The pyrene units attached to the surface of the CdSe nanoparticles associate with the surfaces of graphene flakes to facilitate formation of the pyrene/CdSe-graphene hybrids. Solutions of the hybrids were prepared simply by adding graphene powder into pyrene/CdSe nanoparticle solutions, followed by sonification at room temperature.

### Example 6

To demonstrate the functionality of a transistor active material, a graphene and Indium Zinc Oxide (IZO) composite transistor was constructed. The composite was synthesized by dissolving 0.1M Zinc Acetate (Zn(OAc)₂) and 0.1M Indium Nitrate (In(NO₃)) in a 2-Methoxyethanol solution. Then 1M ethanolamine was added into the 2-Methoxyethanol solution as a stabilizer. 1.5 g/L graphene flakes were added into the IZO solution and sonicated for 1 hour to disperse the graphene. The IZO/graphene solution was spin coated on a silicon nitrite (Si₃N₄) substrate at a speed of 2500 rpm and baked at 200° C. for 10 minutes. One layer of film around 25 nm to 30 nm thick was produced. After spin coating several layers of the film, the sample was annealed at 400° C. to 500° C. in the air. The sample was etched into small stripes by HCl (10% vol.) within 20 seconds following the photolithography defined mask. A second photolithography was used to define the source/drain electrodes and Ti/Au was deposited as the electrode metals completing the device.

Back gate measurements showed that mixed with graphene, the film can get larger on-current, which was 5 times larger than observed with the pure IZO sample. The larger on-current demonstrates that the IZO/graphene composite material has a much higher effective mobility than IZO itself.

### Example 7

To illustrate the functionality of networks of oxide nanosheets and carbonaceous materials, composites of carbon nanotubes and oxide nanosheets were prepared and evaluated. Two fabrication avenues for the multiple networks were utilized. In one embodiment, carbon nanotube films were fabricated first, and then the nano-structured materials were deposited later. Alternatively, carbon nanotubes and nano-structured materials were co-dispersed in a solution, followed by a solution based deposition, utilizing conventional printing processes.

Initially, TiO₂ nanosheets were prepared with a simple hydrothermal route using tetrabutyl titanate, Ti(OBu)₄, as a source and hydrofluoric acid solution as the solvent. The two solutions were mixed in an autoclave at high temperature, above 180° C. After cooling to room temperature, centrifugation was used to separate the product, followed by washings with ethanol and water.

Alternatively, 5 mL of benzyl alcohol, 2 mL of oleylamine, and 0.25 mL of titanium isopropoxide were reacted under solvothermal conditions at 180° C. for 24 hours. The products were precipitated with ethanol and washed with chloroform and ethanol. To render the TiO₂ water-soluble, the oleylamines were exchanged with tetrabutylammonium hydroxide by stirring the TiO₂ in a solution of tetrabutylammonium hydroxide in ethanol for about 1 week. The resulting TiO₂ nanosheets were stored in ethanol for electrode processing.

Composite electrodes incorporating the TiO₂ nanosheets were prepared for evaluation. Carbon nanotubes were mixed with polyvinylidene fluoride (PVDF) binder (5 wt. %) in N-methyl-2-pyrrolidone solvent. The mixture was sonicated for 1 hour. The TiO₂ nanosheets that were dispersed in ethanol were then added to the mixture and sonicated. The resulting slurry was drop cast onto a stainless steel current collector of an appropriate length and width. The electrode/current collector was placed into an oven to evaporate the solvent and create a robust electrode.

In another embodiment produced for comparison, a solution containing oxide nanosheets was deposited directly on top of carbon nanotube (CNT) networks that were previously fabricated followed by incubation and rapid shaking of the electrode. In such a multiple network, the CNT network acts as the current collector and the additional coating of oxide was the active material. This geometry was fundamentally different from composites where all materials are mixed together and potentially interrupting the current paths within the CNT network.

Multiple networks of oxide nanosheets and carbon nanotubes, if properly optimized can lead to electrodes that have high specific capacitance C/gr and high electrical conductivity. In addition, other nano-structured carbons such as activated carbons can also be incorporated into the structure. As an example, TiO₂ (anatase) nanosheets were prepared and measured as described above have an electrochemical capacitance of C=490 F/gr while carbon nanotubes have a capacitance of 100 F/gr and activated carbon 120 F/gr. With a typical composition of 50% of TiO₂ nanosheets and 45% of activated carbon and 5% of carbon nanotubes, the resulting electrochemical capacitance is approximately C=300 F/gr.

Electrodes using two conductive carbon components and an oxide component were also constructed and evaluated. The composite electrodes were prepared with dispersed TiO₂ nanosheets, carbon nanotubes and activated carbon.

The electrodes were prepared by mixing activated carbon (60 wt. %) with a polyvinylidene fluoride (PVDF) binder (5 wt. %) in a N-methyl-2-pyrrolidone solvent and sonicated. Then, TiO₂ nanosheets (30 wt. %) dispersed in ethanol were added to the mixture and again sonicated. The mixture was placed in a fan oven at 120° C. to evaporate the ethanol. Once all ethanol had been removed, the remaining slurry was sonicated again for to ensure homogeneity. Carbon nanotubes (5 wt. %) were then added to the mixture, which was sonicated for 30 minutes. The resulting slurry was drop cast onto a stainless steel current collector of an appropriate length and width. In order to enhance the charge propagation from the oxide to the electrically conducting carbon nanotubes, activated carbon can also be mixed before ball milling, resulting in a three component composite.

### Example 8

Different supercapacitor configurations that have two electrodes were constructed and evaluated. A typical supercapacitor device according to the invention is composed of an oxide nanosheet/carbon nanostructure electrode as the anode and carbonaceous nano-structured material as the cathode can be used. Another preferred device architecture includes two different composite electrodes, where each electrode has an oxide nanostructure utilizing a different type of oxide. For example, in one preferred embodiment, a composite electrode that included an oxide material, such as TiO₂ or V₂O₅ was used as the anode and a composite containing a lithium containing oxide such as Li₂MSiO₄ (where M=Fe, Co, Ni, Mn) was used as cathode. This configuration capitalizes on the high electrochemical capacitance and both anode and cathode, leading to a large overall device capacitance.

Electrochemical characterization was performed in three-electrode cells in an argon-filled glovebox. For the lithium-ion experiments, the cell consisted of lithium foil counter and reference electrodes and 1 M LiClO₄ in ethylene carbonate/dimethyl carbonate (EC/DMC) electrolyte. For the sodium-ion experiments, the cell consisted of a sodium foil counter and reference electrodes and 1 M NaClO₄ in propylene carbonate (PC) electrolyte. For the magnesium-ion experiments, the cell consisted of magnesium counter and reference electrodes and 1 M MgClO₄ in PC electrolyte.

Initially, the lithium ion charge storage capability of the cell using composite electrodes was conducted. The apparatus was conditioned at 10 mV/s for the first 13 cycles because it was observed that the current increases significantly during the first 10 cycles, probably due to ion-exchange of tetrabutylammonium with lithium. When the electrode is soaked in 1 M LiClO₄ in propylene carbonate overnight, this conditioning is no longer necessary.

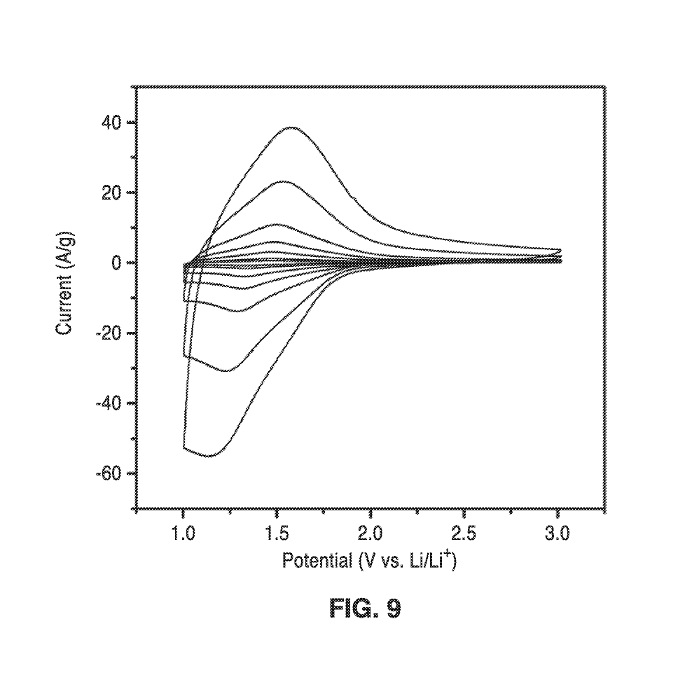

Cyclic Voltammetry (CV) from 1 to 100 mV/s of the lithium cell is shown in FIG. 9. It was observed that the shape of the CV and the potential for lithium insertion and deinsertion seen in FIG. 9 are very different from that observed with anatase TiO₂ nanocrystals grown in the a-b direction. The CV was much broader and the potentials are lower by about 0.5 V.

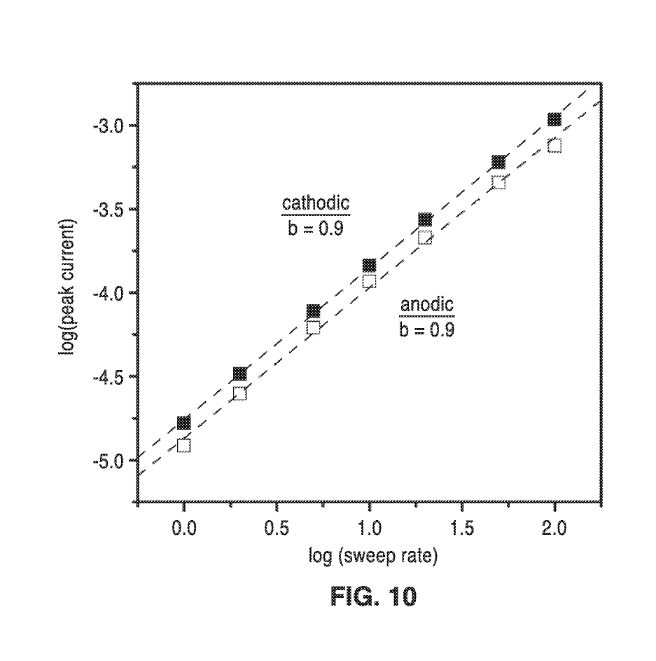

FIG. 10 is a plot of the log(peak current) vs. log(sweep rate) to determine the b-value (i˜av^{b}). The b-value is approximately 0.9 for both the anodic and cathodic peak currents, and an excellent linear fit is achieved from 1 to 100 mV/s. This indicated that the kinetics are under capacitive control in the time regime from approximately 17 minutes to 10 seconds.

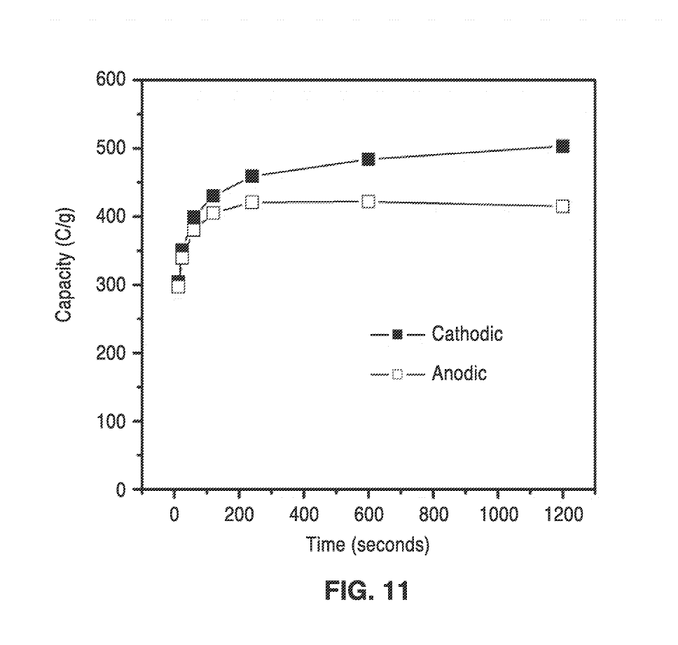

Capacity verses time for lithium insertion (cathodic) and de-insertion (anodic) was plotted and shown as FIG. 11. There is significant coulombic inefficiency observed at slower sweep rates (˜1-5 mV/s) due to the reactivity of the electrolyte near 1 V (vs. Li/Li⁺). The highly exposed surface area and small weight of the material exacerbated the problem. At 100 mV/s (10 seconds), the capacity is shown to be approximately 300 C/g or 300 F/g.

For comparison, similar evaluations were made for sodium ion and magnesium ion cells. For the first 8 cycles at 10 mV/s in the sodium cell, the current was seen to decrease with cycling, unlike in the Li⁺ case.

Cyclic Voltammetry (CV) results from 1 to 100 mV/s of the sodium cell was also conducted. The electrode turned blue during sodium insertion and bleached during sodium de-insertion, indicating that sodium ions are able to insert into the structure. This is quite different from anatase TiO₂ nanocrystals, which do not support sodium-ion intercalation.

The plot of the log(peak current) verses log(sweep rate) indicated a b-value of 1 and 0.83 for the cathodic and anodic peak current, respectively. The insertion and de-insertion processes have a slightly different kinetic behavior than with lithium.

The capacity versus time for sodium insertion (cathodic) and de-insertion (anodic) was also plotted. The coulombic efficiency at slow sweep rates was observed to be good because the operating potential is a little higher in a sodium cell than in a lithium cell. The capacity with Li⁺ and Na⁺ containing electrolytes was also compared. The total capacity was seen to be significantly lower in sodium than in a lithium-ion containing electrolyte.

From the discussion above it will be appreciated that the invention can be embodied in various ways, including the following:

1. An interpenetrating network assembly, comprising a network of connected flakes of nano-scale crystalline carbon; and nano-particles of an electrochemical material in contact with the carbon flakes.

2. The assembly of any preceding embodiment, wherein the electrochemical material is a material selected from the group of materials consisting essentially of an oxide, a sulphide and a selenide.

3. The assembly of any preceding embodiment, wherein the electrochemical material is an oxide selected from the group of oxides consisting essentially of NiO, SiO₂, TiO₂, MnO₂, MoO₃, V₂O₅, and RuO₂.

4. The assembly of any preceding embodiment, further comprising electrically conductive nano-particles selected from the group of particles consisting essentially of Ag nanowires, ZnO nanowires, ITO nanowires, semiconducting nanowires, polyaniline nanofibers, carbon nanotubes, activated carbon and carbon black.

5. The assembly of any preceding embodiment, further comprising electroactive nano-particles selected from the group of particles consisting essentially of NiO, SiO₂, TiO₂, MnO₂, MoO₃, V₂O₅, and RuO₂.

6. The assembly of any preceding embodiment, wherein the nano-scale crystalline carbon comprises graphene.

7. The assembly of any preceding embodiment, further comprising at least one charge collector electrically coupled to the connected flakes of nano-scale crystalline carbon, wherein charge is conducted through connected flakes of crystalline carbon to the charge collector.

8. The assembly of any preceding embodiment, wherein the electrochemical material is a material selected from the group of materials consisting essentially of an oxide, a sulphide and a selenide.

9. The assembly of any preceding embodiment, wherein the electrochemical material is an oxide selected from the group of oxides consisting essentially of NiO, SiO₂, TiO₂, MnO₂, MoO₃, V₂O₅, and RuO₂.

10. The assembly of any preceding embodiment, further comprising electrically conductive nano-particles selected from the group of particles consisting essentially of activated carbon, carbon nanotubes, and carbon black.

11. The assembly of any preceding embodiment, further comprising electrically conductive nano-particles selected from the group of conductors consisting essentially of Ag, Ni, Pt, Au, InP, Si, and GaN.

12. The assembly of any preceding embodiment, wherein the optical transparency of the interpenetrating network is larger than 80% at 550 nm wavelength of light.

13. The assembly of any preceding embodiment, further comprising electroactive nano-particles selected from the group of particles consisting essentially of NiO, SiO₂, TiO₂, MnO₂, MoO₃, V₂O₅, and RuO₂.

14. An interpenetrating network assembly, comprising a source and a drain; a network of connected flakes of nano-scale crystalline carbon bridging the source and the drain; and nano-scale particles of an electrochemical material interconnected with the carbon flakes.

15. The assembly of any preceding embodiment, wherein the nano-scale particles are interconnected flakes of an electrochemical material that bridges the source and the drain.

16. The assembly of any preceding embodiment, wherein the electrochemical material is a material selected from the group of materials consisting essentially of an oxide, a sulphide or a selenide.

17. The assembly of any preceding embodiment, wherein the electrochemical material is an oxide selected from the group of oxides consisting essentially of NiO, SiO₂, TiO₂, MnO₂, MoO₃, V₂O₅, and RuO₂.

18. The assembly of any preceding embodiment, further comprising electrically conductive nano-particles selected from the group of particles consisting essentially of Ag nanowires, ZnO nanowires, ITO nanowires, polyaniline nanofibers, carbon nanotubes, activated carbon and carbon black.

19. An interpenetrating network assembly, comprising a source and a drain; a network of connected flakes of graphene bridging the source and the drain; a network of connected nano-scale flakes of an electrochemical material in contact with said carbon flakes bridging the source and the drain; nanoparticles of an electrical conductor in contact with the interconnected flakes of electrochemical material and flakes of graphene; and nanoparticles of a second electrochemical material in contact with said interconnected flakes of electrochemical material, nanoparticles of electrical conductor and flakes of graphene.

20. The assembly of any preceding embodiment, wherein the electrically conductive nano-particles are selected from the group of particles consisting essentially of metallic nanowires, semiconductor nanowires, ZnO nanowires, ITO nanowires, polyaniline nanofibers, Si nanowires, and Ni nanowires.

21. The assembly of any preceding embodiment, wherein the electrically conductive nano-particles are selected from the group of particles consisting essentially of activated carbon, carbon nanotubes, and carbon black.

22. The assembly of any preceding embodiment, wherein the electrically conductive nano-particles are conductive nanowires made from the group of conductors consisting essentially of Ag, Ni, Pt, Au, InP, Si, and GaN.

23. The assembly of any preceding embodiment, wherein the second electrochemical material is an oxide selected from the group of oxides consisting essentially of NiO, SiO₂, TiO₂, MnO₂, MoO₃, V₂O₅, and RuO₂.

24. The assembly of any preceding embodiment, wherein the second electrochemical material is in the form of nanowires.

25. An interpenetrating network electrode assembly, comprising: a network of connected nano-scale conductive particles; a plurality of nano-scale crystalline sheets of electrochemical material connected to the network of conductive particles; and a current collector coupled to the network of conductive particles.

26. An interpenetrating network electrode assembly, comprising: a network of connected nano-scale conductive particles; a plurality of nano-scale crystalline sheets of electrochemical material connected to the network of conductive particles; amorphous carbon in contact with the network of conductive particles and sheets of electrochemical material; and a current collector coupled to the network of conductive particles.

27. The assembly of any preceding embodiment, wherein the electrochemical material is a material selected from the group of materials consisting essentially of an oxide, a sulphide and a selenide.

28. The assembly of any preceding embodiment, wherein the nano-scale conductive particles are carbon particles selected from the group of particles consisting essentially of polyaniline nanofibers, carbon nanotubes, activated carbon and carbon black.

29. The assembly of any preceding embodiment, wherein the nano-scale conductive particles are particles selected from the group of particles consisting essentially of Ag, Ni, Pt, Au, InP, Si, and GaN nanowires.

30. An electrochemical assembly, comprising: a first electrode of a network of connected carbon nanostructures, nano-scale flakes of a first electrochemical material and a current collector; a second electrode of carbon and a current collector; an electrolyte in contact with the first and second electrodes; and a separator disposed between the first and second electrodes.

31. An electrochemical assembly, comprising: a first electrode of a network of connected carbon nanostructures, nano-scale flakes of a first electrochemical material and a current collector; a second electrode of a network of connected carbon nanostructures, nano-scale flakes of a second electrochemical material and a current collector; an electrolyte in contact with the first and second electrodes; and a separator disposed between the first and second electrodes.

32. The assembly of any preceding embodiment, said first electrode further comprising nanoparticles of amorphous carbon in contact with the network of carbon nanostructures and flakes of electrochemical material.

33. The assembly of any preceding embodiment, said second electrode further comprising nanoparticles of amorphous carbon in contact with the network of carbon nanostructures and flakes of electrochemical material.

34. A sensor assembly, comprising a source and a drain; a single graphene flake bridging the source and the drain; and at least one receptor molecule that changes electronic conformation in response to an environmental stimulus interacting with the graphene sheet; wherein conductance across the graphene sheet changes with the change of each receptor molecule.

35. The assembly of any preceding embodiment, wherein the receptor molecule comprises a pyrene.

36. The assembly of any preceding embodiment, wherein the pyrene receptor molecule comprises a porphyrin.

37. The assembly of any preceding embodiment, wherein the receptor molecule comprises a quantum dot of a semiconductor selected from the group of semiconductors consisting essentially of CdSe, CdS, and CdSe/ZnS.

38. An array of transistors with one graphene flake as the conducting channel each in contact with nano-scale functional materials.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An interpenetrating network assembly, comprising:
a network of connected flakes of nano-scale crystalline carbon; and
nano-particles of an electrochemical material in contact with said carbon flakes.

2. An assembly as recited in claim 1, wherein the electrochemical material is a material selected from the group of materials consisting essentially of an oxide, a sulphide and a selenide.

3. An assembly as recited in claim 2, wherein the electrochemical material is an oxide selected from the group of oxides consisting essentially of NiO, SiO₂, TiO₂, MnO₂, MoO₃, V₂O₅, and RuO₂.

4. An assembly as recited in claim 1, further comprising electrically conductive nano-particles selected from the group of particles consisting essentially of Ag nanowires, ZnO nanowires, ITO nanowires, semiconducting nanowires, polyaniline nanofibers, carbon nanotubes, activated carbon and carbon black.

5. An assembly as recited in claim 1, further comprising electrically conductive nano-particles selected from the group of conductors consisting essentially of Ag, Ni, Pt, Au, InP, Si, and GaN.

6. An assembly as recited in claim 1, further comprising a plurality of a second electroactive nano-particle selected from the group of particles consisting essentially of NiO, SiO₂, TiO₂, MnO₂, MoO₃, V₂O₅, and RuO₂.

7. An assembly as recited in claim 1, further comprising at least one charge collector electrically coupled to said connected flakes of nano-scale crystalline carbon, wherein charge is conducted through connected flakes of crystalline carbon to the charge collector.

8. An assembly as recited in claim 7, wherein the optical transparency of the interpenetrating network is larger than 80% at 550 nm wavelength of light.

9. An interpenetrating network electrode assembly, comprising:
a network of connected nano-scale carbon particles;
a plurality of nano-scale crystalline flakes of electrochemical material connected to the network of conductive particles; and
a current collector coupled to the network of conductive particles.

10. An assembly as recited in claim 9, wherein the carbon nano-particles are selected from the group of particles consisting essentially of graphene, activated carbon, carbon nanotubes, and carbon black.

11. An assembly as recited in claim 9, wherein the electrochemical material is a material selected from the group of materials consisting essentially of an oxide, a sulphide or a selenide.

12. An assembly as recited in claim 9, wherein the electrochemical material is an oxide selected from the group of oxides consisting essentially of NiO, SiO₂, TiO₂, MnO₂, MoO₃, V₂O₅, and RuO₂.

13. An assembly as recited in claim 9, wherein the electrochemical material is an oxide selected from the group of oxides consisting essentially of Li₄Ti₅O₁₂, LiMn₂O₄, LiFePO₄ and LiFeSO₄F.

14. An assembly as recited in claim 9, further comprising electrically conductive nano-particles in contact with the network of carbon and nano-scale flakes of electrochemical material selected from the group of particles consisting essentially of ZnO nanowires, ITO nanowires, polyaniline nanofibers, carbon nanotubes, activated carbon and carbon black.

15. An assembly as recited in claim 9, further comprising electrically conductive nanowires in contact with the network of carbon and nano-scale flakes of electrochemical material selected from the group of conductors consisting essentially of Ag, Ni, Pt, Au, InP, Si, and GaN.

16. An assembly as recited in claim 9, further comprising a plurality of nano-scale crystalline flakes of a second electrochemical material connected to the network of conductive particles.

17. A sensor assembly, comprising:
a source and a drain;
a single graphene flake bridging the source and the drain; and
at least one receptor molecule that changes electronic conformation in response to an environmental stimulus interacting with the graphene sheet; wherein conductance across the graphene sheet changes with the change of each receptor molecule.

18. An assembly as recited in claim 17, wherein said receptor molecule comprises a pyrene.

19. An assembly as recited in claim 17, wherein said pyrene receptor molecule comprises a porphyrin.

20. An assembly as recited in claim 17, wherein said receptor molecule comprises a quantum dot of a semiconductor selected from the group of semiconductors consisting essentially of CdSe, CdS, and CdSe/ZnS.
